(19) United States
(12) Patent Application Publication
(10) Pub. No.: US 2022/0049095 A1
(43) Pub. Date: Feb. 17, 2022

(54) PERMANENT BONDING AND PATTERNING MATERIAL

(71) Applicant: Brewer Science, Inc., Rolla, MO (US)

(72) Inventors: Xiao Liu, Rolla, MO (US); Baron Huang, Taipei City (TW); Reihaneh Sejoubsari, Greenvale, NY (US); Chia-Hsin Lee, Taoyuan City (TW)

(21) Appl. No.: 17/402,926

(22) Filed: Aug. 16, 2021

Related U.S. Application Data
(60) Provisional application No. 63/065,727, filed on Aug. 14, 2020.

(51) Int. Cl. C08L 79/08; B81C 1/00; G03F 7/039; G03F 7/11; G03F 7/20; G03F 7/32; G03F 7/16; G03F 7/38

(52) U.S. Cl. CPC C08L 79/085; B81C 1/00269; B81C 1/00055; B81C 1/00111; G03F 7/38; G03F 7/11; G03F 7/2004; G03F 7/325; G03F 7/162; G03F 7/0392

(57) ABSTRACT

Methods are disclosed to prepare permanent materials that can be coated onto microelectronic substrates or used for other structural or optical applications. The permanent materials are thermally stable to at least 300° C., cure using a photo or thermal process, exhibit good chemical resistance (including during metal passivation), and have a lifespan of at least 5 years, preferably at least 10 years, in the final device. Advantageously, these materials can also be bonded at room temperature. The materials exhibit no movement or squeeze-out after bonding and adhere to a variety of substrate types. A chip-to-chip, chip-to-wafer, and/or wafer-to-wafer bonding method utilizing this material is also described.

### RELATED APPLICATIONS

The present application claims the priority benefit of U.S. Provisional Patent Application Ser. No. 63/065,727, filed Aug. 14, 2020, entitled PERMANENT BONDING AND PATTERNING MATERIAL, incorporated by reference in its entirety herein.

### BACKGROUND

### Field

This invention pertains to permanent materials useful for bonding or coating of semiconductor substrates.

### DESCRIPTION OF RELATED ART

Permanent bonding adhesive materials can be used for a number of technology areas, including CMOS image sensors, 3D IC applications, MEMS, and wafer- and panel-level packaging (WLP and PLP, respectively).

Currently available permanent bonding materials for these applications have limitations, including limited long-term stability, limited temperature stability (below glass transition temperature), and lower bonding strengths. There are concerns over epoxy resins derived from bisphenol A or cresol. Many customers cannot use materials that contain antimony or other heavy metals, which precludes antimony-containing photoacid generators. Additionally, bisphenol A use may be limited due to health and environmental concerns. Similarly, some applications cannot use silicone-containing materials. Benzocyclobutene (“BCB”), a widely used bonding adhesive in these applications, has challenges in achieving void-free adhesive bonding with simultaneous high post-bonding alignment accuracy.

A permanent bonding material suitable for hybrid bonding technologies is necessary to facilitate high-density metal interconnects for heterogeneous integration. Inorganic dielectric materials like SiOx or SiNx typically require ultraflat and/or ultraclean surfaces to obtain desired bonding performance and yield. Some other methods using BCB or polyimides as alternative dielectric materials for hybrid bonding also require chemical mechanical polishing (“CMP”) or other planarization steps to obtain an ultraflat bonding surface. Moreover, bonding BCB or polyimides requires higher temperature processing (>250° C.), which is undesirable for packaging technology development.

### SUMMARY

The present disclosure is broadly concerned with a method of forming a microelectronic structure. The method comprises providing a substrate having a back surface and a front surface, with the substrate optionally including one or more intermediate layers on the front surface. A composition is applied to the front surface, or to the one or more intermediate layers, if present, to form a bonding layer. The composition comprises a bismaleimide dispersed or dissolved in a solvent system. After the bonding layer is formed, at least one of (A), (B), or (C) is performed:
(A) attaching a die or a wafer comprising at least one die to the bonding layer;
(B) forming a photoresist layer on the bonding layer;
   forming a pattern in the photoresist layer; and
   transferring the pattern to the bonding layer to form a patterned bonding layer; or
(C) exposing the bonding layer to laser energy so as to remove at least a portion of the bonding layer.

In another embodiment, a microelectronic structure is provided. The structure comprises a microelectronic substrate having a surface and optionally one or more intermediate layers on the substrate surface. There is an uppermost intermediate layer on the substrate surface, if one or more intermediate layers are present. A bonding layer is on the uppermost intermediate layer, if present, or on the substrate surface, if no intermediate layers are present. The bonding layer comprises at least one of a bismaleimide or a crosslinked bismaleimide and at least one of:
(A) a die on or in the bonding layer;
(B) a wafer comprising at least one die on the bonding layer;
(C) a patterned photoresist layer on the bonding layer; or
(D) a carrier wafer on the bonding layer.

In a further embodiment of the invention, a temporary bonding method is provided. This method comprises providing a stack comprising a first substrate having a back surface and a front surface. The first substrate optionally includes one or more intermediate layers on the front surface. A bonding layer is on the front surface, or on the one or more intermediate layers, if present. The bonding layer comprises one or both of a bismaleimide or a crosslinked bismaleimide. The bonding layer is on the first surface of a s second substrate. The bonding layer is exposed to laser or other energy so as to facilitate separation of the first and second substrates.

In yet a further embodiment, the disclosure provides a bonding method comprising providing a first substrate having an upper surface. There is a first set of features chosen from pads, pillars, microbumps, or combinations thereof formed in or on the upper surface. A photosensitive composition is applied to the upper surface so as to cover at least some of the first set of features and form a bonding layer. The composition comprises a compound dispersed or dissolved in a solvent system. Some of the bonding layer is removed so as to uncover at least some of the first set of features, yielding a patterned bonding layer. The patterned bonding layer is exposed to energy, and a second substrate is bonded to the first substrate. The second substrate comprises a second set of features having a pattern configured to be received within the patterned bonding layer so that at least some of the first set of features contacts at least some of the second set of features. Energy exposure can be carried out before substrate bonding, or substrate bonding can be carried out before exposing to energy.

In another embodiment, a microelectronic structure is provided, where the structure comprises a first substrate having an upper surface. The upper surface comprises a first set of features chosen from pads, pillars, microbumps, or combination thereof formed in or on the upper surface. There are gaps between the first set of features, and a bonding layer is in those gaps. The bonding layer comprises at least one of a bismaleimide or a crosslinked bismaleimide. A second substrate is bonded to the first substrate. The second substrate has an upper surface comprising a second set of features chosen from pads, pillars, microbumps, or combinations thereof formed in or on the upper surface of the second substrate. At least some of the second set of features are in contact with at least some of the first set of features.

### BRIEF DESCRIPTION OF THE DRAWINGS

FIG. 1 is a schematic depiction (not to scale) of a die-attaching process according to one embodiment of the invention;

FIG. 2 is a schematic drawing (not to scale) of a process according to another embodiment of the invention where the bonding layer is patterned by dry etching, using a patterned photoresist as an etch mask;

FIG. 3 is a cross-sectional view of a schematic drawing of a temporary bonding process according to another embodiment of the invention;

FIG. 4 is a cross-sectional view of a schematic drawing of a chip-to-wafer bonding process according to a further embodiment of the invention;

FIG. 5 is a cross-sectional view of a schematic drawing of a wafer-to-wafer bonding process according to yet another embodiment of the invention;

FIG. 6 shows a photo image of the entire grinded wafer (center photo) as well as several microscope images (50×) of the edges of the grinded wafer, showing a lack of edge defects, as described in Example 4;

FIG. 7 shows a photo image of the entire grinded wafer (center photo) as well as several microscope images of the edges of the wafer, which had been grinded down to 30 μm and lacked edge defects, as described in Example 6;

FIG. 8 is a microscope image (200×) of the patterned and bonded wafer pair described in Example 10 (using the Example 8 composition), with the image being taken through the glass wafer;

FIG. 9 is a microscope image of the patterned and bonded wafer pair described in Example 12 (using the Example 11 composition), with the image being taken through the glass wafer;

FIG. 10 is a microscope image (200×) of the patterned and bonded wafer pair described in Example 13 (using the Example 9 composition), with the image being taken through the glass wafer;

FIG. 11 is a scanning electron microscope (“SEM”) image (2,500×) of the patterned wafer formed in Example 15; and

FIG. 12 shows a photo image of die bonding performed as described in Example 16.

### DETAILED DESCRIPTION

The present invention is concerned with compositions and methods of using those compositions for die-attach processes and other permanent bonding processes, for forming patterned layers, and/or for temporary wafer bonding.

### Compositions

The inventive compositions are formed by mixing a compound and any optional ingredients in a solvent system. The resulting composition is stable at room temperature and can be coated easily onto microelectronic substrates.

### 1. Preferred Compounds

Preferred compounds can be polymeric, oligomeric, monomeric, or even a mixture thereof, and preferably comprise recurring units or moieties of maleimides.

A bismaleimide is particularly preferred. In one embodiment, the bismaleimide comprises a moiety chosen from

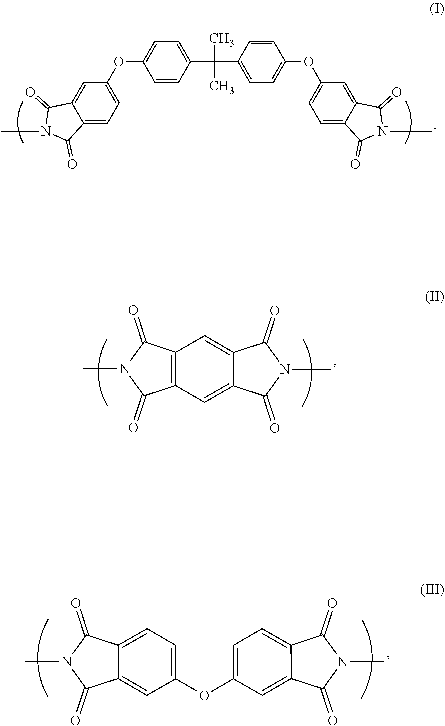

(I) and (II), (II) and (III), (I) and (III), or (I), (II), and (III).

In one embodiment, the bismaleimide comprises 1 to about 15 of the above moieties, and preferably 1 to about 10 of the above moieties.

In another embodiment, the bismaleimide comprises:

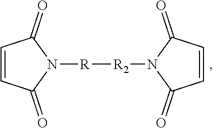

where each R is individually chosen from:

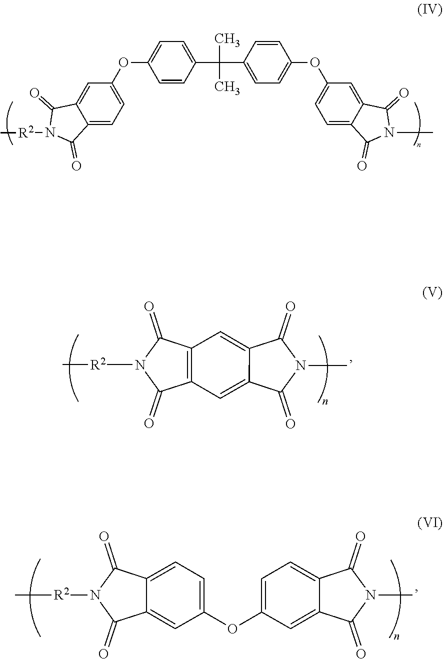

each R² is individually chosen from various linking groups; and

each n is individually 1 to about 15, and preferably 1 to about 10.

Preferred linking groups include any number of hydrocarbon moieties, including alkyls (preferably C₁ to about C₃₆, more preferably about C₆ to about C₁₈, and even more preferably about C₁₂ to about C₁₈), aryls (preferably C₆ to C₁₈, and most preferably C₆), cyclics (preferably about C₅ to C₁₈, more preferably about C₆ to about C₁₂, and even more preferably C₆), and combinations thereof. In a particularly preferred embodiment, the linking group comprises a cyclic and/or aromatic moiety as described above, with 1, 2, 3, 4, 5, or 6 alkyl chains as also described above. Preferably 1 or 2 of the alkyl chains are responsible for connecting the linking group to the remainder of the bismaleimide.

Preferred bismaleimides are sold under the names BMI-1400, BMI-1500, BMI-1700 BMI-3000, and BMI-5000 by Designer Molecules (San Diego, Calif.). Those structures are:

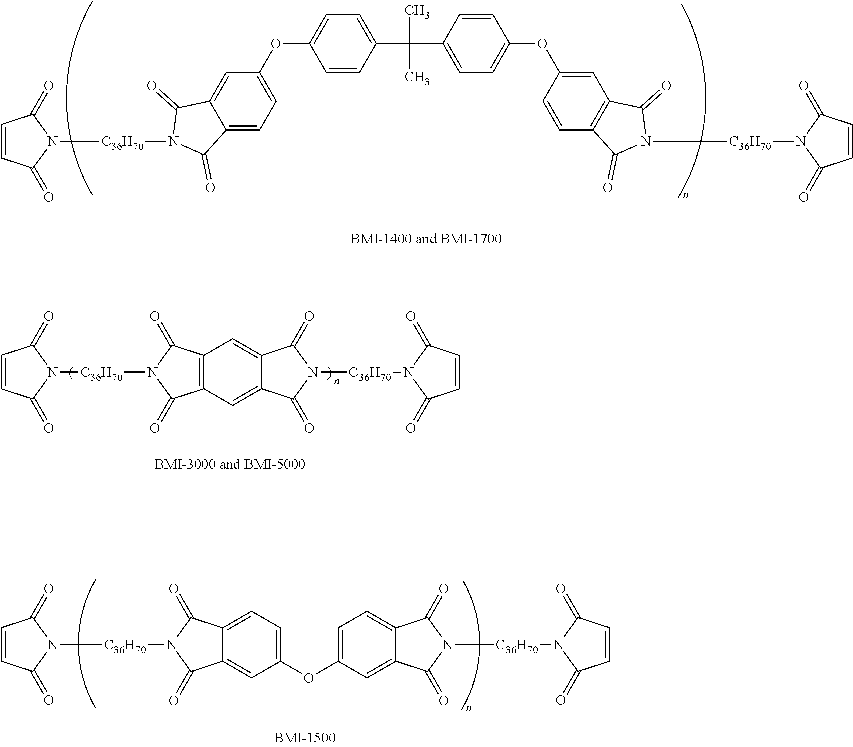

Note that the linking groups C₃₆H₇₀ or C₃₆H₇₂ are not necessarily alkyl chains but could be a blend of different types of hydrocarbon moieties, as described above. For example, here is the linking group R² for BMI-3000 and BMI-5000 fully drawn:

Preferred bismaleimides have a weight average molecular weight of about 500 Daltons to about 8,000 Daltons, preferably about 1,000 Daltons to about 5,000 Daltons, more preferably about 1,000 Daltons to about 3,000 Daltons, and even more preferably about 1,000 Daltons to about 2,000 Daltons.

Regardless of the chosen compound, that compound(s) is preferably present in the composition at levels of about 10% to about 90% by weight, more preferably about 20% to about 70% by weight, and even more preferably about 50% to about 60% by weight, based upon the total weight of the composition taken as 100% by weight.

### 2. Solvent

Suitable solvent systems include a single solvent or solvent mixture. Exemplary solvents include, but are not limited to, ethyl lactate, cyclopentanone, cyclohexanone, methyl isoamyl ketone, isoamyl acetate, propylene glycol methyl ether acetate (PGMEA), propylene glycol methyl ether (PGME), mesitylene, anisole, d-limonene, and mixtures thereof. The solvent system is present in the material from about 20% by weight to about 80% by weight, and preferably from about 30% by weight to about 70% by weight, based upon the total weight of the composition taken as 100% by weight, with the balance of those percentages being taken up by the solids in the composition. It will be appreciated that the amount of solvent or solvents added to the composition may be different depending on the deposition method utilized.

### 3. Comonomers

Comonomers may be added to the material in order to improve the photosensitivity and/or polymerization efficiency. Suitable comonomer systems include, but are not limited to, tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers (such as the one sold under the name LIVELink™ by Brewer Science, Inc.), 1H-Pyrrole-2,5-dione, 1,1′-C36-alkylenebis-, and mixtures thereof. The comonomer(s) is present in the material from about 1% by weight to about 50% by weight, preferably from about 2% to about 30% by weight, and more preferably from about 5% to about 20% by weight, based upon the total weight of the composition taken as 100% by weight. The comonomers are selected depending on the desired properties and use of the final composition.

### 4. Additives

Optionally, additives may be included in the composition. Examples of potential additives include, but are not limited to, crosslinking agents, initiators, surfactants, wetting agents, adhesion promoters, dyes, colorants and pigments, and/or other polymers and resins. These additives would be selected depending on the desired properties and use of the final composition.

Dyes may be added to the material to achieve appropriate optical properties for applications such as laser ablation. When used, suitable dyes include, but are not limited to, bis(benzylidene malononitrile), trimethylolpropane triglycidyl ether—4-methoxybenzylidene pyruvic acid, and mixtures thereof. When a dye is included, it is present in the material from about 0.1% to about 30% by weight, preferably from about 1% to about 20% by weight, and more preferably from about 5% to about 10% by weight, based upon the total weight of the composition taken as 100% by weight. The dye can be mixed into the composition, or it can be attached to the compound.

Suitable initiators include, but are not limited to, 9,10-phenanthrenequinone, 4,4′-bis(diethylamino)benzophenone, 2-hydroxy-2-methyl propiophenone (such as DAROCUR® 1173 by Ciba), dicumyl peroxide, benzoyl peroxide, bis-acylphosphine oxide (such as Omnirad 819 from IGM Resins), ethyl (2,4,6-trimethylbenzoyl)-phenyl-phosphinate (such as Omnirad TPO-L by IGM Resins), oxime ester photoinitiators (such as Irgacure OXE 01 or Irgacure OXE 02 from BASF), and mixtures thereof. When a photoinitiator is used, it is present in the material at a level of about 0.1% to about 10% by weight, preferably about 0.3% to about 7% by weight, and more preferably from about 0.5% to about 5% by weight, based upon the total weight of the composition taken as 100% by weight.

Suitable surfactants include, but are not limited to, nonionic fluorinated surfactants, such as MEGAFACE R-30N (DIC Corporation), F-556 (DIC Corporation), and mixtures thereof. When used, the surfactant is present in the material from about 0.01% by weight to about 0.5% by weight, and preferably from about 0.01% to about 0.2% by weight, based upon the total weight of the composition taken as 100% by weight.

Suitable adhesion promoters include, but are not limited to, methacryloxypropyltrimethoxysilane, 3-glycidyloxypropyltrimethoxysilane, pyromellitic dimethacrylate, pyromellitic dianhydride glycerol dimethacrylate, 4-methacryloxyethyl trimellitic, and mixtures thereof. When used, the adhesion promoter is present in the composition from about 0.05% to about 5% by weight, and preferably from about 0.1% to about 3% by weight, based upon the total weight of the composition taken as 100% by weight.

In one embodiment, the composition consists essentially of, or even consists of, the compound dispersed or dissolved in the solvent system. In a further embodiment, the composition consists essentially of, or even consists of, the compound (and preferably a bismaleimide); at least one of an initiator, a comonomer, and/or an adhesion promoter; and a solvent system.

Regardless of the embodiment, the resulting composition is stable at room temperature and can be coated easily onto microelectronic substrates. As used herein, “stable” means that the composition can be stored for periods of at least about 180 days and preferably from about 360 days to about 720 days with less than about 0.1% of precipitation or separation of the solids from the solution.

### Methods of Use

Advantageously, the disclosed compositions are suitable for use in microelectronic structures, optical applications, and structural applications, including as a permanent layer or component in the particular structure or device.

Methods of using the composition involve applying the composition to a substrate to form a layer of the composition thereon. The substrate can be any microelectronic substrate. In embodiments where the substrate is a device substrate, the substrate utilized will preferably include topography (e.g., contact holes, via holes, raised features, and/or trenches). This topography can be included directly on the substrate surface, or it can be included in one or more layers of other material formed on the substrate surface. Preferred substrates include those commonly used in front-end and back-end applications. When the substrate is a carrier substrate, the substrate utilized will generally not include topography. Particularly preferred substrates are chosen from silicon, aluminum, tungsten, tungsten silicide, gallium arsenide, germanium, tantalum, tantalum nitrite, silicon germanium, glass, copper, chrome, zinc, silicon oxide, silicon nitride (SiN), and combinations thereof.

The compositions can be coated onto the substrate by spin coating, slot-die coating, ink jet printing and other methods compatible with the application of solvent-based coating formulations. These techniques may require the adjustment of the polymer solids level in the solution to obtain the desired coating thickness and uniformity without defects, for example, by diluting the solution with the principal solvent and/or adding co-solvents that do not cause polymer precipitation. A preferred method of application is spin coating at speeds from about 800 rpm to about 2,500 rpm, and more preferably from about 1,000 rpm to about 1,500 rpm for a time period of from about 20 seconds to about 60 seconds, and preferably from about 30 seconds to about 40 seconds.

After application to the substrate, the composition is solvent baked to evaporate any residual solvent. The solvent bake temperature should be from about 60° C. to about 150° C., and preferably from about 60° C. to about 120° C. This heating step is preferably carried out for a time period of from about 1 second to about 6 minutes, and more preferably from about 60 seconds to about 4 minutes. It will be appreciated that the solvent bake may be performed in more than one step, that is, it may be first baked at a lower temperature, followed by a second bake at a higher temperature.

In some embodiments, the composition is cured after the solvent bake and any intermediate steps. In other embodiments, bonding is carried out prior to curing. In either instance, curing is preferably carried out by a thermal or photo process, depending upon whether an initiator was included and, if so, whether it was a thermal initiator or a photoinitiator. For thermal curing (i.e., a thermal initiator is included in the composition), the composition should be heated to above its crosslinking temperature, preferably from about 180° C. to about 250° C., and more preferably from about 200° C. to about 250° C. for a time period of from about 10 minutes to about 60 minutes, and preferably from about 10 minutes to about 30 minutes. For photo curing (i.e., a photoinitiator is included in the composition), the composition may be cured by exposure to radiation, such as UV or visible radiation. Exposure wavelengths vary based on chemistry, but are preferably from about 200 nm to about 500 nm, and more preferably from about 300 nm to about 400 nm, for a time period of from about 60 seconds to about 15 minutes, and preferably from about 60 seconds to about 5 minutes. The exposure dose varies based on the chemistry but is preferably from about 3 mJ/cm² to about 50 mJ/cm², and more preferably from about 10 mJ/cm² to about 30 mJ/cm².

The coatings preferably have a thickness (average measurements taken over five locations by an ellipsometer) of between about 1 μm and about 20 μm, and more preferably about 3 μm to about 10 μm. Advantageously, a coating thickness of about 5 μm has relatively low curing stress, which prevents substrate bowing, and thus makes the wafer/substrate processable in post-coating processes.

Additionally, because the materials have the property of crosslinking in response to UV radiation, this allows the materials to be molded, cast into form, etc., by thermoplastic processing and then hardening by UV exposure, thus forming a free-standing film or laminate that can be adhered to a substrate at the time of use. Alternately, areas within the film can be selectively hardened by patterned exposure, for example, to create regions that are stiffer or more thermally stable. Regardless of whether crosslinking is allowed to happen over time or is caused to happen via thermal or photocuring, bridges will form between the above-described compounds, causing the material to go from thermoplastic in nature to thermoset.

Advantageously, these materials may be used for a variety of semiconductor packaging processes. Depending on the process, intermediate steps may be performed between the initial coating and solvent bake of the material before curing. Exemplary process flows utilizing these materials in conjunction with the above conditions (unless stated otherwise) are described below.

### 1. Die Attach Process

Referring to FIG. 1, a substrate 10 is provided, with the substrate 10 having a front surface 12 and a back surface 14. Substrate 10 can be any of the substrates described above. A layer 16 of a composition as described above is applied to front surface 12 and solvent baked, as described above. Layer 16 has an upper surface 18 and a lower surface 20, with its lower surface 20 being in contact with front surface 12 of substrate 10. Next, dies 22 are attached to upper surface 18 of layer 16, and the composition is cured. Curing will take place over time or can be effected by thermal curing or photocuring, depending upon whether an initiator is utilized and, if so, the type of initiator. Regardless, the dies 22 are now attached to permanent bonding layer 16. Next, vias 24 can be drilled (e.g., by laser drilling) through the substrate 10 from the direction of back surface 14. A metal layer 26 is then deposited into vias 24 and on back surface 14 following conventional metallization processes and further processing steps (e.g., passivation, patterning, redistribution layer (“RDL”) formation, singulation, electroplating, plasma etching, cleaning, chemical vapor deposition, physical vapor deposition, and combinations of the foregoing) can then be carried out, depending upon the particular application and end user goals.

Although FIG. 1 shows dies 22 being attached to permanent bonding layer 16, it will be appreciated that the same process can also be used to attach a wafer comprising one or more dies to the permanent bonding layer 16.

### 2. Photopatterning Process

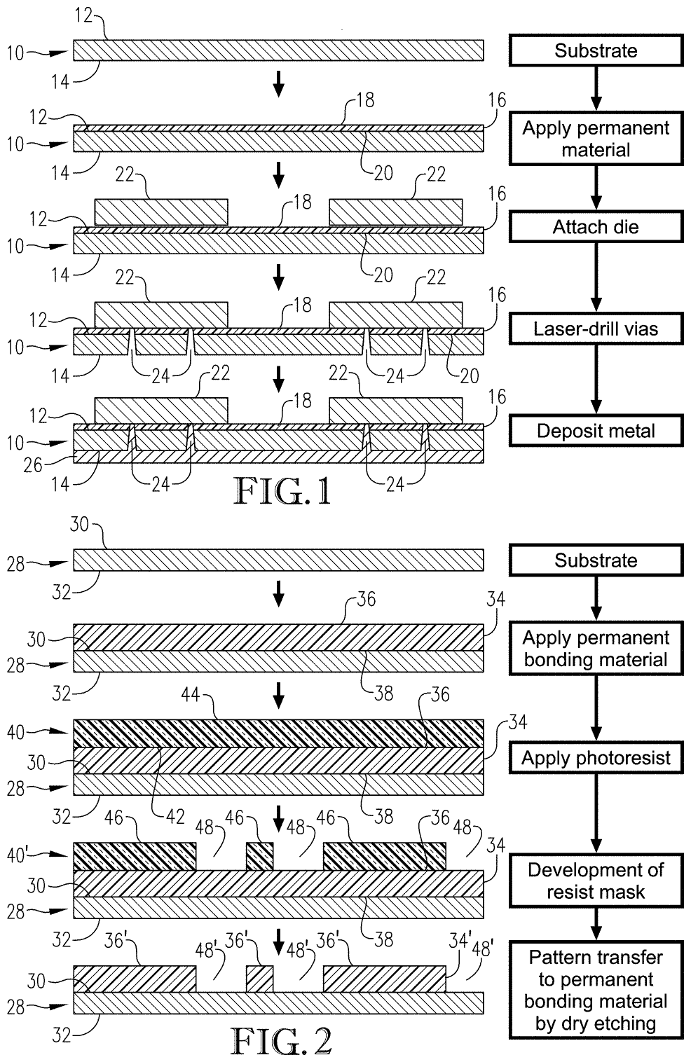

Referring to FIG. 2, a substrate 28 is provided, with the substrate 28 having a front surface 30 and a back surface 32. Substrate 28 can be any of the substrates described above. A layer 34 of a composition as described above is applied to front surface 30 and solvent baked, as described above. Layer 34 has an upper surface 36 and a lower surface 38, with its lower surface 38 being in contact with front surface 30 of substrate 28. After solvent baking, the layer 34 is cured or allowed to cure, as described above.

Next, a conventional photoresist composition is applied (following conventional processes) to upper surface 36 of layer 34, so as to form photosensitive layer 40 having lower surface 42 and upper surface 44, with lower surface 42 being in contact with upper surface 36 of layer 34 (i.e., of the layer formed from a composition according to the inventive embodiments described herein). The photoresist layer 40 is dried or baked, per the manufacturer's instructions. The photoresist layer 40 is then exposed to UV light through a mask (not shown) having the desired pattern. One of ordinary skill in the art will understand how to form the pattern, including taking into account whether the photoresist is positive-acting or negative acting. Additionally, the exposure wavelength, dose, etc., can be determined by the skilled artisan based on the photoresist's chemistry and/or manufacturer's recommendations. After exposure and any post-exposure bake, the photoresist layer 40 is developed using an aqueous developer so as to form a patterned photoresist layer 40′. Patterned photoresist layer 40′ has portions 46 remaining after development as well as “voids” 48 that were removed during development. Portions 46 and voids 48 cooperate to form the patterned photoresist layer 40′, which can now be used as an etch mask to dry etch (e.g., using CF₄ etchant) the inventive layer 34, transferring the pattern from patterned photoresist layer 40′ down to the inventive layer 34, thus forming patterned layer 34′ having remaining portions 36′ and “voids” 48′, corresponding to those of patterned photoresist layer 34′. Subsequent processing steps can now be performed using the patterned permanent bonding material. For example, one or more dies or a wafer comprising at least one die (not shown) can be attached to patterned layer 34′. In those instances, the remaining portions 36′ or voids 48′ can be used as a template for locations to fix the one or more dies or other structures. Other processing that could be carried out at this stage includes die encapsulation, hermetic sealing, and/or hybrid bonding.

### 3. Bonding Process

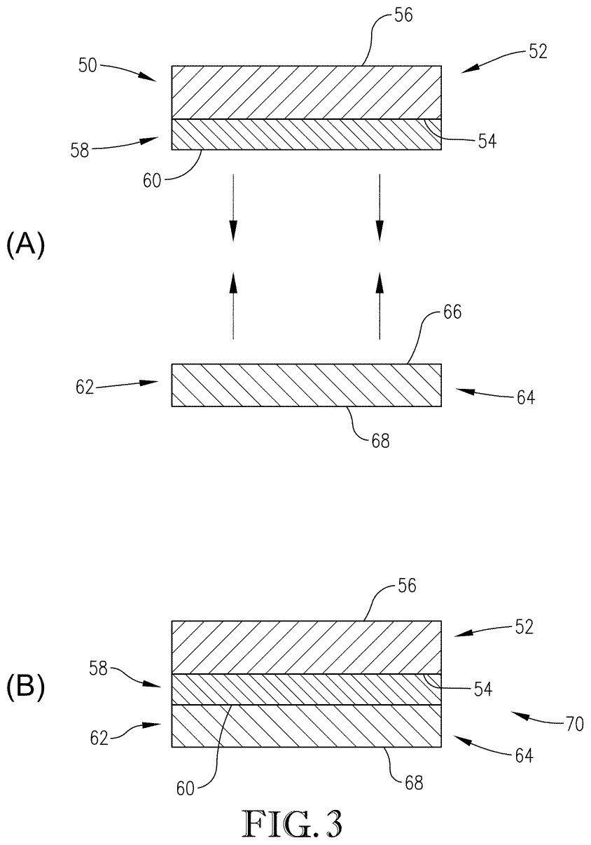

Referring to FIG. 3(A) (not to scale), a precursor structure 50 is depicted in a schematic and cross-sectional view. Structure 50 includes a first substrate 52. Substrate 52 has a front or device surface 54 and a back surface 56. Preferred first substrates 52 include device wafers such as those whose device surfaces comprise arrays of devices (not shown) selected from the group consisting of integrated circuits, MEMS, microsensors, power semiconductors, light-emitting diodes, photonic circuits, interposers, embedded passive devices, and other microdevices fabricated on or from silicon and other semiconducting materials such as silicon-germanium, gallium arsenide, gallium nitride, aluminum gallium arsenide, aluminum indium phosphide, and indium gallium phosphide. The surfaces of these devices commonly comprise structures (again, not shown) formed from one or more of the following materials: silicon, polysilicon, silicon dioxide, silicon (oxy)nitride, metals (e.g., copper, aluminum, gold, tungsten, tantalum), low k dielectrics, polymer dielectrics, and various metal nitrides and silicides. The device surface 54 can also include at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

A composition according to the invention is applied to the first substrate 52 (following the steps described previously) to form a bonding layer 58 on the device surface 54, as shown in FIG. 3(a). Bonding layer 58 has an upper surface 60 remote from first substrate 52. The bonding layer 50 can be formed directly on the device surface 54 (i.e., without any intermediate layers between the bonding layer 58 and substrate 52), or one or more intermediate layers (not shown; e.g., hardmask layer, spin-on carbon layer, dielectric layer, release layer, etc.) could first be formed on device surface 54, and bonding layer 58 can then be formed directly on the uppermost intermediate layer. Regardless, bonding layer 58 is applied and solvent baked following the steps described previously.

A second precursor structure 62 is also depicted in a schematic and cross-sectional view in FIG. 3(a). Second precursor structure 62 includes a second substrate 64. In this embodiment, second substrate 64 is a carrier wafer and has a front or carrier surface 66 and a back surface 68. Although second substrate 64 can be of any shape, it would typically be shaped and sized similarly to first substrate 52. Preferred second substrates 64 include a clear wafer or any other transparent (to laser energy) substrate that will allow the laser energy to pass through the carrier substrate, including, but not limited to, glass, Corning Gorilla glass, and sapphire. One especially preferred glass carrier wafer is a Corning EAGLE XG glass wafer.

After the solvent bake noted above, the two substrates 52 and 64 are bonded together in a face-to-face configuration under pressure, with the permanent bonding material (i.e., the composition described herein) between the two substrates along with any additional intermediate layers, so as to form bonded stack 70 (FIG. 3(B)). Preferred bonding pressures are from about 100 N to about 5,000 N, and more preferably from about 1,000 N to about 3,000 N. Preferred bonding times are from about 30 seconds to about 5 minutes, and more preferably from about 30 seconds to about 2 minutes. Preferred bonding temperatures are from about 20° C. to about 120° C., and more preferably from about 30° C. to about 70° C. In one embodiment, bonding is preferably carried out at room temperature.

The bonding layer 58 adheres to a variety of substrate types and will not exhibit movement or “squeeze-out” after bonding. First substrate 52 can now be safely handled and subjected to further processing that might otherwise have damaged first substrate 52 without being bonded to second substrate 64. For example, the structure can be subjected to backside processing such as back-grinding, chemical-mechanical polishing (“CMP”), etching, metal deposition (i.e., metallization), dielectric deposition, patterning (e.g., photolithography, via etching), passivation, annealing, and combinations thereof, without separation of substrates 52 and 64 occurring, and without infiltration of any chemistries encountered during these subsequent processing steps. In one embodiment, the bonded stack 70 may remain bonded permanently during and after the subsequent processing steps.

In another embodiment, once processing is complete, the substrates 52 and 64 can be separated by using a laser to decompose or ablate all or part of the bonding layer 58. This is particularly useful in embodiments where the composition used to form bonding layer 58 included a dye. Suitable laser wavelengths include from about 200 nm to about 400 nm, and preferably from about 300 nm to about 360 nm. In order to debond the bonding layer 58, a laser is scanned across the surface of the substrate 64 in a stand-and-repeat method or line scan method in order to expose the entire wafer. Exemplary laser debonding tools include the SUSS MicroTec Lambda STEEL 2000 laser debonder and Kingyoup laser debonder. The substrate 64 is preferably scanned by the laser spot with a field size from about 40×40 μm to about 12.5×4 mm. Suitable fluence to debond the substrates 52, 64 is from about 100 mJ/cm² to about 400 mJ/cm², and preferably from about 150 mJ/cm² to about 350 mJ/cm². Suitable power to debond the substrates 52, 64 is from about 0.5 W to about 6 W, and preferably from about 1 W to about 2 W. After laser exposure, the substrates 52 and 64 will readily separate. After separation, any remaining bonding layer 58 can be removed with a plasma etch or a solvent capable of dissolving the bonding layer 58.

Alternatively, debonding can be carried out by mechanically disrupting, cutting, and/or dissolving bonding layer 58.

In the above embodiments, the bonding layer 58 is shown on a first substrate 52 that is a device wafer. It will be appreciated that this substrate/layer scheme could be reversed. That is, the bonding layer 58 could be formed on second substrate 64 (the carrier wafer). The same compositions and processing conditions would apply to this embodiment as those described above.

### 4. Alignment and Bonding Process

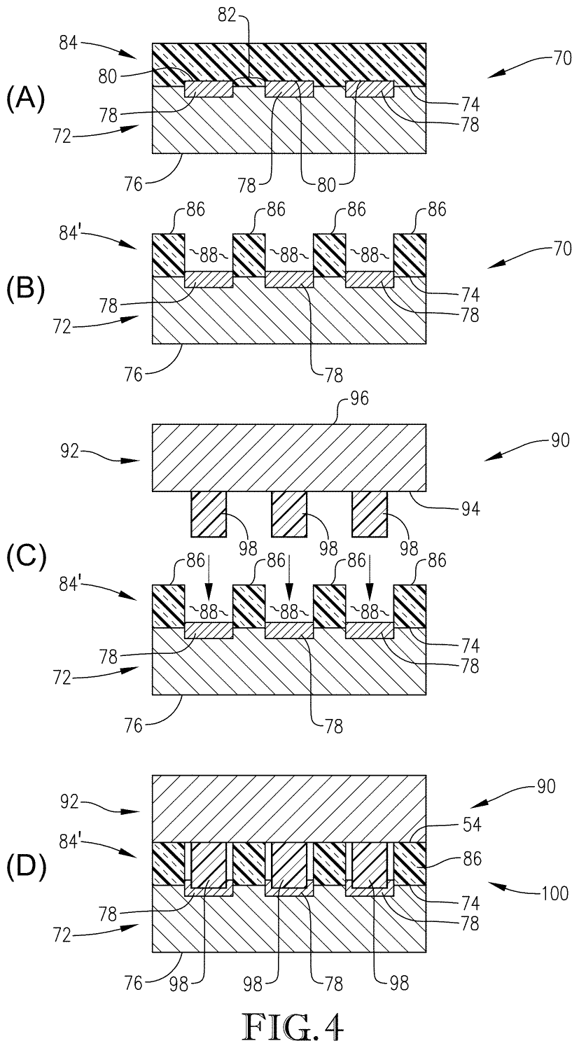

Referring to FIG. 4(A) (not to scale), a precursor structure 70 is provided. Precursor structure 70 includes a first substrate 72. First substrate 72 has a front surface 74 and a back surface 76. Front surface 74 includes a plurality of features 78. Features 78 can be the same or different, and they are chosen from metal contacts such as bump or die pads, pillars, microbumps, and combinations thereof. Microbumps are generally spherical in shape, and pillars are generally cylindrical in shape. Each typically has a pitch of no more than about 40 μm, preferably no more than about 30 μm, and down to submicron in size (e.g., about 1 μm). Bump or die pads are flat conductive areas to which electrical connections can be attached, such as wires, solder balls, pillars, or microbumps. The bump or die pads, microbumps, and pillars can be formed of any conventional material, including those chosen from Cu, Sn, CuSn, SnAg, Al, Au, AlOx, Ti, Ta, conductive epoxy, and combinations thereof. In some embodiments, a very thin layer of material is deposited over the features 78 by atomic layer deposition to prevent oxidation or other damage.

Features 78 have respective upper surfaces 80 and present gaps or spaces 82 therebetween. It will be appreciated that the size of the gaps 82 between features 78 will be selected pursuant to the user's particular needs and design, as is conventional. A photosensitive bonding composition, such as those described previously, is applied to front surface 74 and upper surfaces 80 following the processes described previously to form a photosensitive layer 84. The photosensitive layer 84 is then exposed to radiation through a mask (not shown) having the desired pattern. Preferably, the mask is designed to permit light to contact those portions of photosensitive layer 84 that are between the features 78, thus rendering the portions exposed to radiation insoluble in a developer or solvent (e.g., cyclopentanone). In this context, “insoluble” means that the exposed portions will experience less than about 1%, and preferably about 0% weight loss when contacted with the developer for a period of about 180 seconds.

After exposure photosensitive layer 84 is preferably soft baked at about 50° C. to about 80° C. for about 3 minutes to about 10 minutes, followed by a second bake at about 100° C. to about 150° C. for about 5 minutes to about 20 minutes. Photosensitive layer 84 is then subjected to a solvent developing step to dissolve and remove the portions of photosensitive layer 84 that were not exposed to radiation (i.e., the portions that remain uncured, and thus soluble, in the developer). As shown in FIG. 4(B), this results in the formation of a patterned layer 84′ that has raised portions 86 and openings 88 between raised portions 86, with openings 88 exposing the features 78. Preferably a thermal or UV curing step is then carried out to ensure complete polymerization of the compound in the photosensitive bonding composition that was used to form photosensitive layer 84.

Referring to FIG. 4(C), a second precursor structure 90 is provided. Structure 90 comprises a second substrate 92. Second substrate 92 has a front surface 94 and a back surface 96. Front surface 94 includes a plurality of features 98. Features 98 can be the same or different, and they are chosen from bump pads, pillars, microbumps, and combinations thereof. It will be appreciated that the pattern formed by features 98 is used as a guide to prepare the patterned photosensitive layer 84′, as described above. That is, the pattern of patterned photosensitive layer 84′ is a negative of the pattern formed by features 98. Additionally, the thickness of patterned photosensitive layer 84′ is chosen so that it corresponds to the respective heights of the features 98. Thus, because openings 88 are configured to receive features 98, alignment of precursor structures 70 and 90 is simplified, as shown in FIG. 4(D), where stack 100 is shown. Stack 100 can now be subjected to bonding as desired, such as in a bonding chamber at a temperature of less than about 200° C., or following the other bonding parameters described previously. Additionally, any gaps between features 78, 98 and the raised portions 86 of patterned photosensitive layer 84′ can be sealed at elevated temperatures (e.g., about 80° C. to about 200° C., preferably about 120° C.) under vacuum for about 1 second to about 60 seconds.

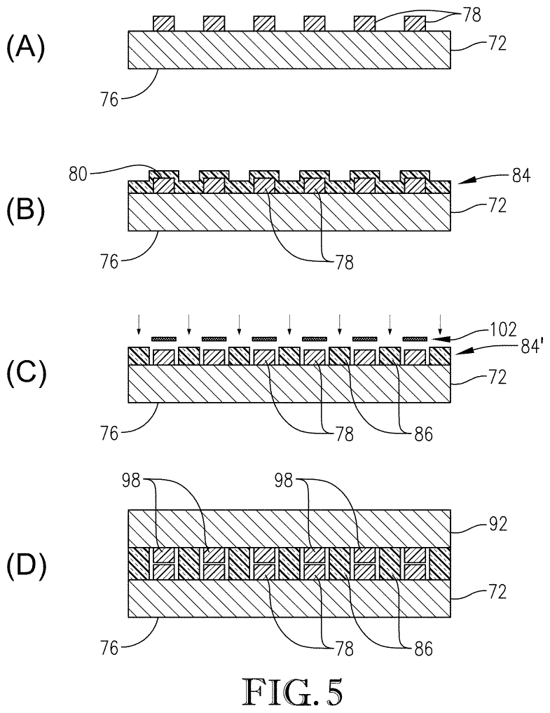

It will be appreciated that the above process allows for a variety of substrate arrangements. FIG. 4 shows a schematic depiction of a “chip-to-wafer” bonding process. That is, in FIG. 4, first substrate 72 of first precursor structure 70 is a wafer while second precursor structure 90 is a chip. In FIG. 5, first substrate 72 is still a wafer, but second precursor structure 90 is also a wafer (i.e., a “wafer-to-wafer” bonding process). (For simplicity's sake, FIG. 5 has been numbered similarly to FIG. 4, with 102 representing the mask used during exposure.) Additionally, FIG. 5 shows a conformal application of the photosensitive bonding composition, whereas FIG. 4 depicts a planarizing application of the photosensitive bonding composition. For a wafer-to-wafer bonding process, the wafers are bonded and sealed at elevated temperatures (e.g., about 100° C. to about 250° C., preferably about 150° C.) under vacuum for about 10 minutes to about 30 minutes.

Finally, in a further embodiment, a “chip-to-chip” bonding process (not shown) can also be carried out. In this embodiment, both first precursor structure 70 and second precursor structure 90 are chips.

It will be appreciated that each of the described “Alignment and Bonding” processes demonstrates similar advantages, including low-temperature bonding (typically below about 200° C.), low temperature curing (below about 200° C.), high tolerance for particles or surface/thickness variation of the substrates, and eliminating the need for CMP or other planarization techniques.

### 5. Laser Patterning Process

In a further embodiment, the compositions described herein can be utilized in a laser patterning process. This is particularly useful in embodiments where the composition includes a dye, as described previously. Any microelectronic substrate can be used in the invention, including those described previously. The method of applying the composition is according to the general methods described previously. The formed layer is patterned by laser ablation, preferably using an excimer laser to expose the layer to laser energy. The laser may be used in a “direct write” fashion in which a small laser beam is rastered only in the areas to be ablated, or the laser may be applied through a metal mask so as to only ablate the areas where the laser is able to pass through the mask. The laser energy is absorbed by the material of layer and as a result of various photochemical and thermal effects, portions of the layer are removed to form a pattern in the layer.

The excimer laser wavelength is preferably from about 200 nm to 450 nm, more preferably from about 250 nm to 400 nm, and even more preferably from about 300 nm to 400 nm. The pulse rate is less than about 4,000 Hz, preferably from about 100 Hz to about 3,500 Hz, more preferably from about 1,000 Hz to about 3,000 Hz, and even more preferably from about 2,000 Hz to about 3,000 Hz. The pulse length can be from about 1 μs to about 100 ps, depending on the type of pulsed laser being used. The amount of material removed is dependent upon the material, laser wavelength, pulse rate, and pulse length.

This selective removal can produce features such as lines of the layer, with spaces between the lines where the material has been removed, or in vias (holes) in the layer, and it will be appreciated that any pattern could be formed by the laser ablation. When lines and spaces are formed using laser ablation, the width of the lines and spaces is preferably less than about 200 microns, more preferably from about 1 micron to about 70 microns, and even more preferably from about 20 microns to about to 60 microns. When vias are formed using laser ablation, the diameter of the vias that are formed is preferably less than about 700 microns, more preferably from about 1 micron to about 500 microns, and even more preferably from about 10 microns to about 300 microns. Advantageously, the sidewalls of the features may be substantially perpendicular to the surface of the substrate, that is, the sidewalls of the features make an angle of preferably from about 70° to about 110° with the surface of the substrate (or of the surface of uppermost of any intermediate layers that are present), and more preferably an angle of about 90° with the surface of the substrate.

### Layer Properties

Regardless of the embodiment, the cured layers formed by the compositions described herein will have excellent thermal and adhesive properties. Materials preferably have a glass transition temperature (T_{g}) of about 30° C. to about 200° C., and more preferably from about 150° C. to about 200° C. The layers will also preferably have high thermal stabilities, with a decomposition temperature (T_{d}) of at least about 300° C., more preferably at least about 330° C., and even more preferably at least about 390° C. Furthermore, these materials preferably have a CTE (coefficient of thermal expansion) of from about 45 ppm/° C. to about 200 ppm/° C.

The cured layers preferably have a tensile elongation of at least about 4%, and more preferably about 120%, and also exhibit low moisture absorption. The layers are capable of adhering well to materials such as copper, chrome, zinc, aluminum, silicon oxide, silicon nitride (SiN), having adhesion of at least about 10 psi, preferably at least about 30 psi, and even more preferably at least about 40 psi when measured by ASTM D4541-17.

In one embodiment, the layers are preferably photosensitive. That is, the layers can be patterned upon exposure to at least about 1 mJ/cm² radiation. Layers that cannot be patterned upon exposure to 1 mJ/cm² radiation are considered non-photosensitive.

The cured materials can also serve as a dielectric material. In such instances, the cured layers will have a dielectric constant of at least about 2.0, and preferably at least about 2.7, with a dielectric loss of from about 0.001 to about 0.01, and preferably from about 0.002 to about 0.008. When used in laser ablation applications as described above, the cured layers preferably have a k value of at least about 0.1, and more preferably at least about 0.15.

The cured materials will also exhibit good chemical resistance (including during metal passivation), where good chemical resistance is tested by soaking the material in the chemical of interest (e.g., tetramethyl ammonium hydroxide (TMAH), PGME, PGMEA, ethyl lactate, cyclopentanone, cyclohexanone) at a temperature of from about room temperature to about 90° C. for a time period of from about 10 minutes to about 30 minutes. Good chemical resistance is demonstrated when the cured material shows no signs of chemical attack upon visual inspection, and there is little or no thickness loss, that is, preferably less than 10% thickness loss, and more preferably less than about 5% thickness loss. The cured materials will preferably have a lifespan of at least 5 years, and more preferably at least 10 years, in the final device.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Bonding Composition 1

In this Example, 45 grams of BMI 1700 (Designer Molecules, San Diego, Calif.) was dissolved in 55 grams of mesitylene. The solution was mixed on a stir wheel until the mixture was homogeneous and filtered with a 0.2-μm filter into a plastic bottle.

### Example 2

### Bonding Composition 2

In this procedure, 45 grams of BMI 1700 and 2 grams of dicumyl peroxide (Sigma-Aldrich, St. Louis, Mo.) were dissolved in 53 grams of mesitylene. The solution was mixed on a stir wheel until the mixture was homogeneous and filtered with a 0.2-μm filter into a plastic bottle.

### Example 3

### Bonding Composition 3 (Comparative

In this Example, 45 grams of Ebecryl 3720 (Allnex, East St Louis, Ill.), 3 grams of methacryl polyhedral oligomeric silsesquionxane (“POSS,” Hybrid Plastics, Hattiesburg, Miss.), and 1.5 grams of dicumyl peroxide (Sigma) were dissolved in 50.5 grams of cyclopentanone. The solution was mixed overnight on a stir wheel and filtered with a 0.2-μm filter into a plastic bottle.

### Example 4

### Processing of Example 2 Composition

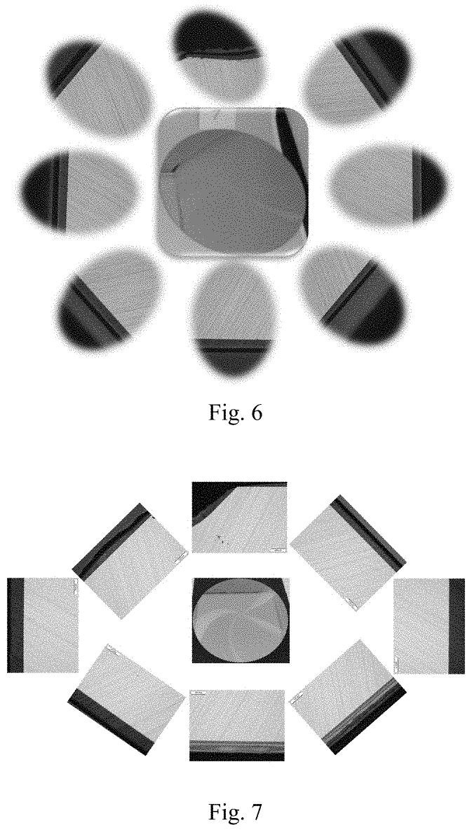

A 5-μm coating of the material from Example 2 was applied to a silicon wafer by spin coating at 1,500 rpm with a ramp of 1,500 rpm/s for 30 seconds. The wafer was then baked at 60° C. for 2 minutes followed by 120° C. for 2 minutes. A glass wafer was aligned and bonded to the silicon wafer using an EVG bonder at 60° C., with a pressure of 2,000 N, for a time of 3 minutes. The material was then cured under a UV lamp (IntelliRay Flood Curing system, i-line wavelength, intensity 115 mW/cm² at 3″ from lamp) for 2 minutes, followed by thermal curing at 220° C. for 5 minutes followed by 250° C. for 5 minutes, giving a void-free bonded wafer pair. The bonded wafer pair was subjected to a grinding test, which was performed by DISCO. All the tested wafers passed grinding down to 20 μm or 30 μm without voids, defects, or edge chipping as shown in FIG. 6.

### Example 5

### Adhesion Testing of Example 2 Composition

The material from Example 2 was tested according to ASTM D4541-17 using a portable, pull-off adhesion tester. Adhesion data was collected by averaging three failure values from each set of tests. Table 1 shows the adherence results on various substrates.

TABLE 1
Adhesion Properties of the Example 2 Composition

| | | | Cu | |
|---|---|---|---|---|
| Silicon | Glass | SiN | Coated | Kapton ® |
| (psi) | (psi) | (psi) | Si (psi) | (psi) |
| 54.8 | 40.2 | 42.0 | 24.4 | 54.2 |

### Example 6

### Processing of Example 3 Composition

A 5-μm coating of the material from Example 3 was applied to a silicon wafer by spin coating at 1,300 rpm with a ramp of 1,500 rpm/s for 30 seconds. The coated wafer was baked at 60° C. for 2 minutes followed by 120° C. for 2 minutes. A glass wafer was then aligned and bonded to the silicon wafer using a EVG bonder at 60° C., with a pressure of 3000 N, for a time of 3 minutes. The material was cured at 230° C. for 30 minutes, giving a void-free bonded wafer pair. The bonded wafer pair was subjected to a grinding test. All the tested wafers passed grinding down to 20 μm or 30 μm without voids, defects, or edge chipping as shown in FIG. 7.

### Example 7

### Adhesion Testing of Example 3 Composition

The Example 3 composition was tested according to ASTM D4541-17 using a portable, pull-off adhesion tester. Adhesion data was collected by averaging three failure values from each set of tests. Table 2 shows the adherence results on a Si wafer under different curing conditions.

TABLE 2
Adhesion properties of Example 3 Composition

| 230° C. | UV 6 min | UV 6 MIN + 230° C. |
|---|---|---|
| (psi) | (psi) | (psi) |
| 52.0 | 16.7 | 35.6 |

### Example 8

### Bonding Composition 4

In this Example, 58 grams of BMI 3000 (Designer Molecules Inc, San Diego, Calif.), 1.2 grams of Irgacure OXE 02 (photoinitiator; BASF, Germany), and 0.3 grams of 3-glycidyloxypropyltrimethoxy silane (TCI Chemical, Japan) were dissolved in 100 grams of mesitylene. The solution was mixed for 6 hours on a stir wheel and filtered with a 0.2-μm filter into a plastic bottle.

### Example 9

### Bonding Composition 5

In this procedure, 58 grams of BMI 1700, 1.2 grams of Irgacure OXE 02, and 0.3 grams of 3-glycidyloxypropyltrimethoxy silane were dissolved in 60 grams of mesitylene. The solution was mixed for 6 hours on a stir wheel and filtered with a 0.2-μm filter into a plastic bottle.

### Example 10

### Processing of Example 8 Composition at 200° C.

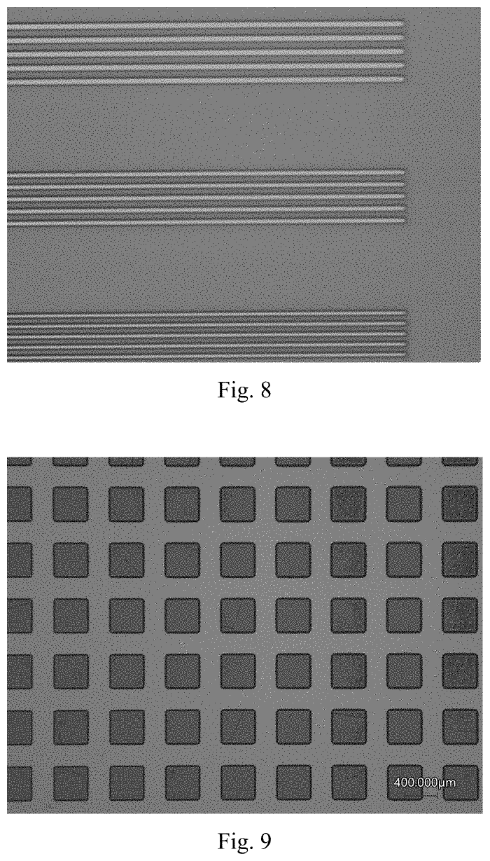

A 5-μm coating of the material from Example 8 was applied to a silicon wafer by spin coating at 1,000 rpm with a ramp of 3,000 rpm/s for 30 seconds. The wafer was then baked at 60° C. for 5 minutes followed by 120° C. for 5 minutes. The coated wafer was patterned using an EVG610 mask aligner at an exposure dose of 100 mJ/cm², followed by developing with cyclohexanone for 3 minutes. A glass wafer was then aligned and bonded to the silicon wafer using a CEE® Apogee® bonder at 200° C., with a pressure of 2,000 N, for a time of 5 minutes, giving a void-free, bonded wafer pair. The bonded wafer pair was cured at 180° C. for 60 minutes as shown in FIG. 8.

### Example 11

### Bonding Composition 6

In this Example, 58 grams of BMI 3000, 1.2 grams of Irgacure OXE 02, and 0.3 grams of 3-glycidyloxypropyltrimethoxy silane were dissolved in 60 grams of mesitylene. The solution was mixed for 6 hours on a stir wheel and filtered with a 0.2-μm filter into a plastic bottle.

### Example 12

### Processing of the Material from Example 11 at 150° C.

A 5-μm coating of the material from Example 11 was applied to a silicon wafer by spin coating at 1000 rpm with a ramp of 3000 rpm/s for 30 seconds. The wafer was then baked at 60° C. for 5 minutes and then 120° C. for 5 minutes. The coated wafer was then patterned using EVG610 mask aligner at exposure dose of 200 mJ/cm², followed by developing with cyclohexanone for 1 minute. A glass wafer was then aligned and bonded to the silicon wafer using a CEE® Apogee® bonder at 150° C., with a pressure of 8000 N, for a time of 15 minutes, giving a void-free bonded wafer pair. The bonded wafer pair was then cured at 200° C. for 60 minutes as shown in FIG. 9.

### Example 13

### Processing of the Material from Example 9

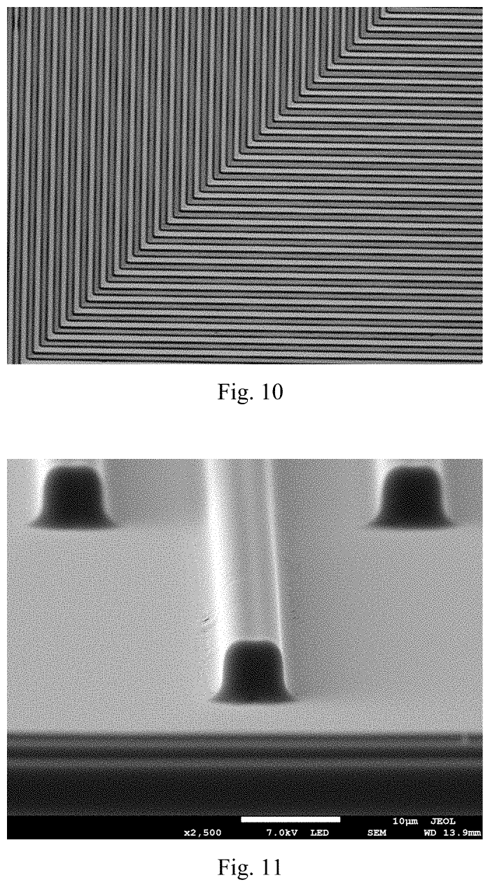

A 10-μm coating of the material from Example 9 was applied to a silicon wafer by spin coating at 1000 rpm with a ramp of 3000 rpm/s for 30 seconds. The wafer was then baked at 60° C. for 5 minutes and then 120° C. for 5 minutes. The coated wafer was then patterned using EVG610 mask aligner at exposure dose of 300 mJ/cm², followed by developing with cyclohexanone for 5 minutes. A glass wafer was then aligned and bonded to the silicon wafer using a CEE® Apogee® bonder at 60° C., with a pressure of 2000 N, for a time of 5 minutes, giving a void-free bonded wafer pair. The bonded wafer pair was then cured at 180° C. for 60 minutes as shown in FIG. 10.

### Example 14

### Bonding Composition 7

In this Example, 30 grams of BMI 3000 and 2.53 grams of tri(ethylene glycol) divinyl ether (Sigma, St. Louis) were dissolved in 30 grams of cyclopentanone and 7.5 grams of mesitylene. The solution was mixed for 24 hours on a stir wheel and filtered with a 0.2-μm filter into a plastic bottle.

### Example 15

### Processing of Example 14 Composition

A 5-μm coating of the Example 14 composition was applied to a silicon wafer by spin coating at 1,500 rpm with a ramp of 3,000 rpm/s for 30 seconds. The wafer was baked at 60° C. for 5 minutes followed by 120° C. for 5 minutes. Next, the coated wafer was patterned using UV lamp (IntelliRay Flood Curing system, i-line wavelength, intensity 115 mW/cm² at 3″ from lamp) for 10 seconds, followed by developing with cyclopentanone/isopropanol (3/1) for 1 minute. The developed wafer went through post-exposure bake at 200° C. for 1 minute. FIG. 11 shows an image of the patterned wafer.

### Example 16

### Processing of Example 11 Composition

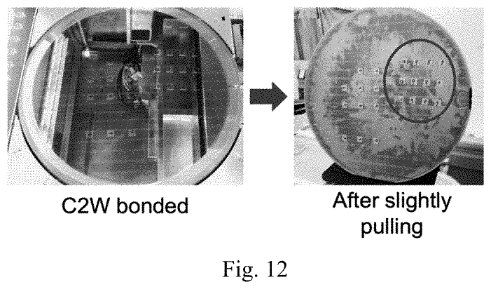

A 5-μm coating of the material from Example 11 was applied to a 200-mm silicon wafer by spin coating at 700 rpm/s with a ramp of 3,000 rpm/s for 30 seconds. The wafer was then baked at 60° C. for 5 minutes followed by 120° C. for 15 minutes. The coated wafer was then patterned using a SUSS MA300 mask aligner at an exposure dose of 200 mJ/cm², followed by developing with cyclohexanone for 2 minutes. The wafer was then baked at 200° C. for 60 minutes to fully cure the bonding material. The coated wafer was subjected to die bonding using dummy 10-mm×10-mm dies at 100° C. for 10 seconds with bonding force ranging from 10 N to 50 N. The use of bonding forces higher than 20 N resulted in 100% yield (i.e., zero failure). Bonded dies are shown in FIG. 12, where “C2W” is an abbreviation for “chip-to-wafer” and “after slightly pulling” refers to the ability of the dies to remain stationary while bonded to the wafer and not move or be removed with light finger pressure.

### Example 17

### Bond Strength of Example 11 Composition

A razor blade was inserted in the edge of the bonded wafer pair from Example 12, then the resulting crack length was measured. Based on the razor blade thickness (h), Young's modulus of the silicon wafer (E), the silicon wafer thickness (t), and the measured crack length (L), the bond energy (BE—see Table 3) of the Example 11 composition was calculated based on the Maszara model.

$$BE ( \frac{m J}{{m}^{2}} ) = \frac{3 \times {h}^{2} \times E \times {t}^{3}}{32 \times {L}^{4}}$$

TABLE 3
Bond Strength of Example 11 Bonding Layer

| Bond Energy | Bond Energy |
|---|---|
| to Silicon Substrate | to Glass Substrate |
| 3762 mJ/m² | 2181 mJ/m² |

We claim:

1. A method of forming a microelectronic structure, said method comprising:
providing a substrate having a back surface and a front surface, said substrate optionally including one or more intermediate layers on said front surface;
applying a composition to said front surface, or to said one or more intermediate layers, if present, to form a bonding layer, said composition comprising a bismaleimide dispersed or dissolved in a solvent system; and
performing at least one of (A), (B), or (C):
(A) attaching a die or a wafer comprising at least one die to said bonding layer;
(B) forming a photoresist layer on said bonding layer;
forming a pattern in said photoresist layer; and
transferring said pattern to said bonding layer to form a patterned bonding layer; or
(C) exposing the bonding layer to laser energy so as to remove at least a portion of the bonding layer.

2. The method of claim 1, wherein said bismaleimide comprises a moiety chosen from 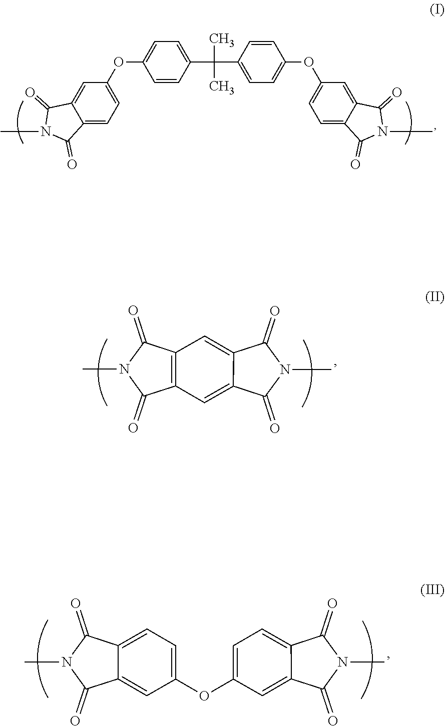
(I) and (II), (II) and (III), (I) and (III), or (I), (II), and (III).

3. The method of claim 2, wherein said bismaleimide comprises 1 to about 15 of said moieties.

4. The method of claim 1, wherein said composition further comprises a compound chosen from comonomers, crosslinking agents, initiators, surfactants, wetting agents, adhesion promoters, dyes, pigments, copolymers, and mixtures thereof.

5. The method of claim 4, wherein said composition comprises a comonomer chosen from tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers, 1H-Pyrrole-2,5-dione, 1,1′-C36-alkylenebis-, and mixtures thereof.

6. The method of claim 1, wherein said composition consists essentially of:
said bismaleimide;
at least one of an initiator, a comonomer, and/or adhesion promoter; and
said solvent system.

7. The method of claim 1, wherein said performing comprises performing (B), and further comprising placing:
a die on or in said patterned bonding layer; or
a wafer comprising at least one die on said patterned bonding layer.

8. A microelectronic structure comprising:
a microelectronic substrate having a surface;
optionally one or more intermediate layers on said substrate surface, there being an uppermost intermediate layer on said substrate surface, if one or more intermediate layers are present;
a bonding layer on said uppermost intermediate layer, if present, or on said substrate surface, if no intermediate layers are present, wherein said bonding layer comprises at least one of a bismaleimide or a crosslinked bismaleimide; and
at least one of
(A) a die on or in said bonding layer
(B) a wafer comprising at least one die on said bonding layer;
(C) a patterned photoresist layer on said bonding layer; or
(D) a carrier wafer on said bonding layer.

9. The structure of claim 8, wherein said bismaleimide comprises a moiety chosen from 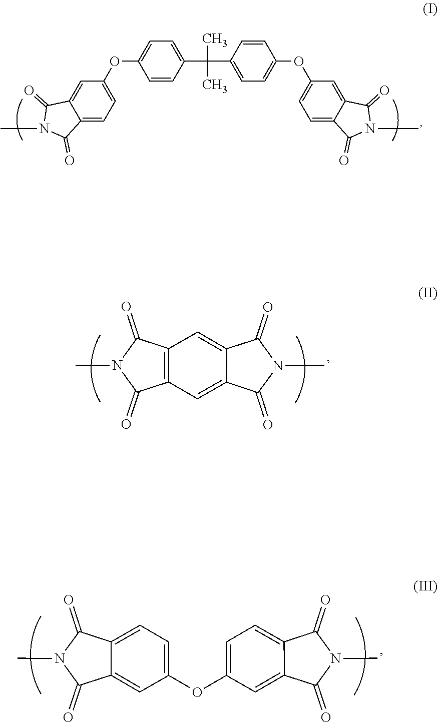
(I) and (II), (II) and (III), (I) and (III), or (I), (II), and (III).

10. The structure of claim 9, wherein said bismaleimide comprises 1 to about 15 of said moieties.

11. The structure of claim 8, wherein said bonding layer further comprises at least one of a comonomer, crosslinking agent, or copolymer.

12. The structure of claim 11, wherein said bonding layer comprises a comonomer chosen from tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers, 1H-Pyrrole-2,5-dione, 1,1′-C36-alkylenebis-, and mixtures thereof.

13. The structure of claim 11, wherein said comonomer is reacted with said bismaleimide.

14. The structure of claim 8, wherein said bonding layer consists essentially of:
one or both of said bismaleimide or said crosslinked bismaleimide; and
at least one of a comonomer and/or copolymer.

15. The structure of claim 8, wherein said microelectronic substrate is selected from the group consisting of silicon substrates, aluminum substrates, tungsten substrates, tungsten silicide substrates, gallium arsenide substrates, germanium substrates, tantalum substrates, tantalum nitrite substrates, silicon germanium substrates, glass substrates, copper substrates, chrome substrates, zinc substrates, silicon oxide substrates, silicon nitride substrates, and combinations thereof.

16. The structure of claim 8, wherein said structure comprises (D), and said carrier wafer comprises a glass substrate.

17. A temporary bonding method comprising:
providing a stack comprising:
a first substrate having a back surface and a front surface, said substrate optionally including one or more intermediate layers on said front surface;
a bonding layer on said front surface, or on said one or more intermediate layers, if present, said bonding layer comprising one or both of a bismaleimide or a crosslinked bismaleimide; and
a second substrate having a first surface, said bonding layer being on said first surface; and
exposing said bonding layer to laser or other energy so as to facilitate separation of said first and second substrates.

18. The method of claim 17, wherein said bismaleimide comprises a moiety chosen from 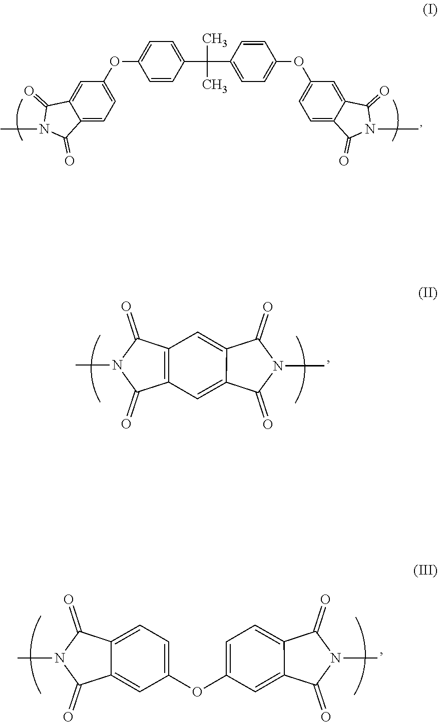
(I) and (II), (II) and (III), (I) and (III), or (I), (II), and (III).

19. The method of claim 18, wherein said bismaleimide comprises 1 to about 15 of said moieties.

20. The method of claim 17, wherein said bonding layer further comprises at least one of a comonomer, crosslinking agent, or copolymer.

21. The method of claim 20, wherein said bonding layer comprises a comonomer chosen from tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers, 1H-Pyrrole-2,5-dione, 1,1′-C36-alkylenebis-, and mixtures thereof.

22. The method of claim 20, wherein said comonomer is reacted with said bismaleimide.

23. The method of claim 17, wherein said composition consists essentially of:
one or both of said bismaleimide or said crosslinked bismaleimide; and
at least one of a comonomer and/or copolymer.

24. The method of claim 17, wherein at least one of said first and second substrates is selected from the group consisting of silicon substrates, aluminum substrates, tungsten substrates, tungsten silicide substrates, gallium arsenide substrates, germanium substrates, tantalum substrates, tantalum nitrite substrates, silicon germanium substrates, glass substrates, copper substrates, chrome substrates, zinc substrates, silicon oxide substrates, silicon nitride substrates, and combinations thereof.

25. The method of claim 17, wherein one of said first and second substrates is a device wafer, and the other of said first and second substrates is a carrier wafer.

26. A bonding method comprising:
a) providing a first substrate having an upper surface, there being a first set of features chosen from pads, pillars, microbumps, or combinations thereof formed in or on said upper surface;
b) applying a photosensitive composition to said upper surface so as to cover at least some of said first set of features and form a bonding layer, said composition comprising a compound dispersed or dissolved in a solvent system;
c) removing some of said bonding layer so as to uncover at least some of said first set of features, yielding a patterned bonding layer;
d) exposing said patterned bonding layer to energy; and
e) bonding a second substrate to said first substrate, said second substrate comprising a second set of features having a pattern configured to be received within the patterned bonding layer so that at least some of said first set of features contacts at least some of said second set of features, where exposing (d) can be carried out before bonding (e), or bonding (e) can be carried out before exposing (d).

27. The method of claim 26, wherein said removing (c) comprises:
selectively exposing portions of said bonding layer to radiation to render the exposed portions insoluble in a developer; and
removing said exposed portions with developer so as to uncover the at least some of said features.

28. The method of claim 26, wherein said exposing (d) comprises exposing said patterned bonding layer to one or both of heat or UV light.

29. The method of claim 26, wherein said first set of features has a pitch of less than about 40 μm.

30. The method of claim 26, wherein said applying (b) results in said bonding layer covering all of said first set of features.

31. The method of claim 26, wherein:
said first substrate and said second substrate comprise chips;
said first substrate and said second substrate comprise wafers; or
wherein said first substrate comprises a wafer and said second substrate comprises a chip.

32. The method of claim 26, wherein no additional layers are applied to said bonding layer before said removing (c).

33. The method of claim 26, said compound comprising a bismaleimide.

34. The method of claim 33, wherein said bismaleimide comprises a moiety chosen from 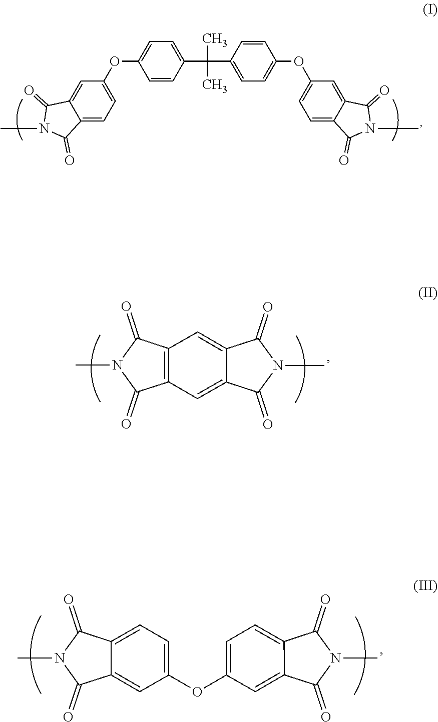
(I) and (II), (II) and (III), (I) and (III), or (I), (II), and (III).

35. The method of claim 34, wherein said bismaleimide comprises 1 to about 15 of said moieties.

36. The method of claim 26, wherein said composition further comprises a compound chosen from comonomers, crosslinking agents, initiators, surfactants, wetting agents, adhesion promoters, dyes, pigments, copolymers, and mixtures thereof.

37. The method of claim 36, wherein said composition comprises a comonomer chosen from tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers, 1H-Pyrrole-2,5-dione, 1,1′-C36-alkylenebis-, and mixtures thereof.

38. The method of claim 33, wherein said composition consists essentially of:
said bismaleimide;
at least one of an initiator, a comonomer, and/or adhesion promoter; and
said solvent system.

39. A microelectronic structure comprising:
a first substrate having an upper surface, there being:
a first set of features chosen from pillars, microbumps, or both pillars and microbumps formed in or on said upper surface; and
gaps between said first set of features;
a bonding layer in said gaps, said bonding layer comprising at least one of a bismaleimide or a crosslinked bismaleimide; and
a second substrate bonded to said first substrate, said second substrate having an upper surface comprising a second set of features chosen from pillars, microbumps, or both pillars and microbumps formed in or on said upper surface of said second substrate, at least some of said second set of features being in contact with at least some of said first set of features.

40. The structure of claim 39, wherein said first set of features has a pitch of less than about 40 μm.

41. The structure of claim 39, wherein:
said first substrate and said second substrate comprise chips;
said first substrate and said second substrate comprise wafers; or
wherein said first substrate comprises a wafer and said second substrate comprises a chip.

42. The structure of claim 38, wherein said bismaleimide comprises a moiety chosen from 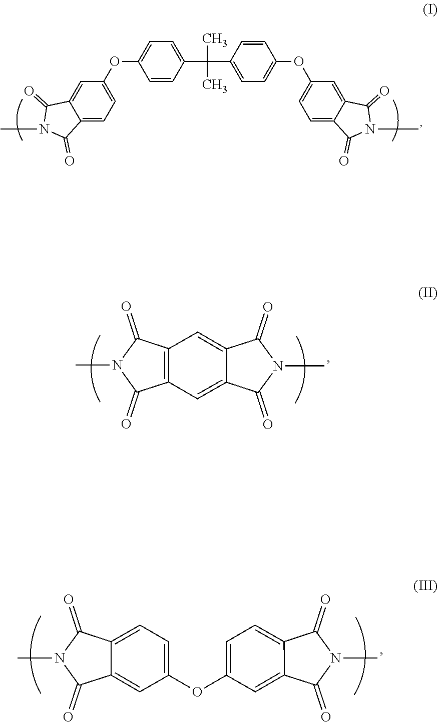
(I) and (II), (II) and (III), (I) and (III), or (I), (II), and (III).

43. The structure of claim 42, wherein said bismaleimide comprises 1 to about 15 of said moieties.

44. The structure of claim 39, wherein said bonding layer further comprises at least one of a comonomer, crosslinking agent, or copolymer.

45. The structure of claim 44, wherein said bonding layer comprises a comonomer chosen from tri(ethylene glycol) divinyl ether, 1,4-butanediol divinyl ether, 1,4-cyclohexanedimethanol divinyl ether, di(ethylene glycol) divinyl ether, poly(ethylene glycol) divinyl ether, divinyl adipate, vinyl ether crosslinkers, 1H-Pyrrole-2,5-dione, 1,1′-C36-alkylenebis-, and mixtures thereof.

46. The structure of claim 44, wherein said comonomer is reacted with said bismaleimide.

47. The structure of claim 39, wherein said bonding layer consists essentially of:
one or both of said bismaleimide or said crosslinked bismaleimide; and
at least one of a comonomer and/or copolymer.
